(19) United States
(12) Patent Application Publication
(10) Pub. No.: US 2006/0148189 A1
(43) Pub. Date: Jul. 6, 2006

(54) Method for forming resistors in semiconductor integrated circuit devices

(75) Inventor: Dong Yeal Keum, Icheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/320,979

(22) Filed: Dec. 30, 2005

(30) Foreign Application Priority Data
Dec. 31, 2004 (KR) 10-2004-0118255

(51) Int. Cl. H01L 21/20

(52) U.S. Cl. 438/382

(57) ABSTRACT

Disclosed is a method for forming resistors in semiconductor integrated circuit device, comprising the steps of: depositing a pad oxide on a semiconductor substrate; depositing silicon nitride on the pad oxide; depositing photoresist on entire surface of the substrate; transferring patterns of trenches to the photoresist to form photoresist pattern, the patterns of trenches including narrow trenches and active dummy layers sandwiched between neighboring narrow trenches; selectively removing the silicon nitride and pad oxide with using the photoresist pattern as a mask; selectively etching the semiconductor substrate at portions that are exposed by the selectively removed silicon nitride and pad oxide to form trenches including the narrow trenches; forming polysilicon lines on the narrow trenches; and forming metal contacts to off-edges of the polysilicon lines.

### CROSS-REFERENCE TO RELATED APPLICATION

This application claims priority to and the benefit of Korean Patent Application No. 10-2004-0118255 filed in the Korean Intellectual Property Office on Dec. 31, 2004, the entire contents of which are incorporated herein by reference.

### BACKGROUND OF THE INVENTION

1. Field of the Invention

The present invention relates to passive components employed in integrated circuit devices and more particularly to method for forming resistors capable of overcoming shallow trench isolation dishing problem.

2. Description of the Related Art

Generally, passive components such as RF band pass filters, inductors, capacitors and resistors are formed on the wide shallow trench isolation (STI) field region for improving noise margin. However, chemical mechanical polishing or planarization (CMP) used in the formation of the STI may introduce undesirable side-effects of dishing in the trench region. The dishing may cause the variation of the width of overlying metal, which is one of the critical factors in electrical characteristics of the passive components, degrade the process quality, cause significant yield losses, and negatively affect electrical characteristics of the components.

For instance, a DC converter 10 has an output gain determined by the ratio of resistors R1 and R2 as shown in FIG. 1, i.e., (R1+R2)/R2. Since the resistors R1 and R2, made of polysilicon lines 12 and 14 are formed on the wide STI field region 22 on a semiconductor substrate 20 for alleviating noise effects, a CMP dishing is observed as shown in FIG. 2. Therefore, the overlying polysilicon lines 12 and 14 for the resistors R1 and R2 have different widths W1 and W2, which results in the difference in the ratio of R1 and R2 from the original value. Consequently, the output gain of the DC converter becomes different from the intended value, and varies from place to place on the wafer according to the amount of dishing.

### SUMMARY OF THE INVENTION

Principles of the present invention, as embodied and broadly described herein, are directed to a method for forming resistors in semiconductor integrated circuit device, comprising the steps of: depositing a pad oxide on a semiconductor substrate; depositing silicon nitride on the pad oxide; depositing photoresist on entire surface of the substrate; transferring patterns of trenches to the photoresist to form photoresist pattern, the patterns of trenches including narrow trenches and active dummy layers sandwiched between neighboring narrow trenches; selectively removing the silicon nitride and pad oxide while using the photoresist pattern as a mask; selectively etching the semiconductor substrate at portions that are exposed by the selectively removed silicon nitride and pad oxide to form trenches including the narrow trenches; forming polysilicon lines on the narrow trenches; and forming metal contacts to off-edges of the polysilicon lines.

The space between each of the polysilicon lines and the edge of the narrow trench on which the polysilicon line is formed is equal to or greater than the depth of the narrow trench. The polysilicon lines may be formed by: depositing undoped polysilicon on the semiconductor substrate; implanting impurity ions into the deposited undoped polysilicon; and annealing the polysilicon to increase grain size and resistivity of the polysilicon. In an embodiment of the present invention, silicided polysilicon is employed for the resistor lines.

### BRIEF DESCRIPTION OF DRAWINGS

The accompanying drawings, which are incorporated in and constitute part of this Specification, depict corresponding embodiments of the present invention, by way of example only, and it should be appreciated that corresponding reference symbols indicate corresponding parts. In the drawings:

FIG. 1 is a schematic diagram showing conventional DC-DC converter and layout of resistors included therein;

FIG. 2 is a cross-sectional view of resistors when taken along the line II-II of FIG. 1;

FIG. 3 is layout diagram of resistors formed according to the present invention;

FIG. 4 is a cross-sectional view of resistors when taken along the line IV-IV of FIG. 3; and

FIG. 5 is a cross-sectional view of resistors according to another embodiment of the present invention.

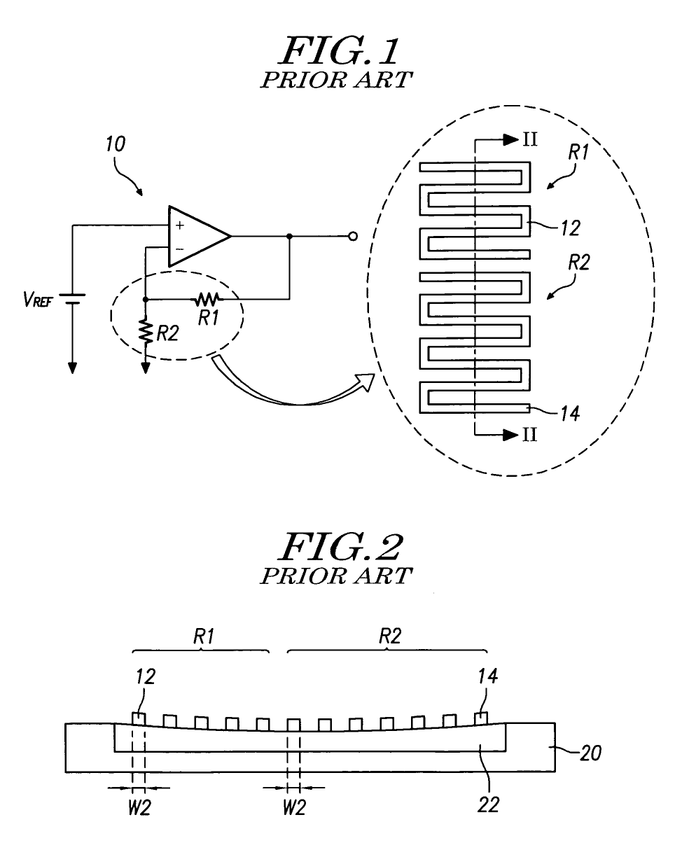

### DETAILED DESCRIPTION OF EMBODIMENTS OF THE INVENTION

Hereinafter, preferred embodiments of the present invention will be described with reference to the accompanying drawings.

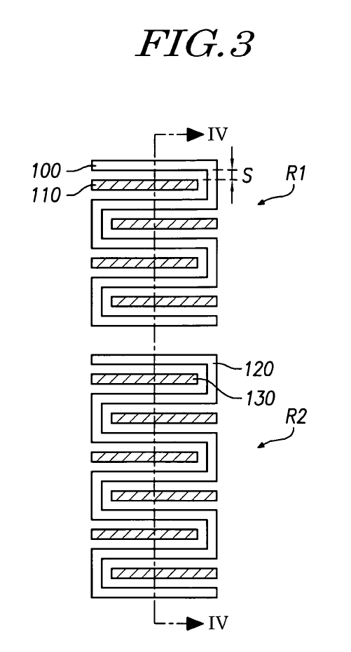

FIG. 3 is layout diagram of resistors formed according to the present invention.

The resistors R1 and R2 of FIG. 3 may be used as passive components in microcircuits such as DC converter. In an embodiment of the present invention, each of the resistors R1 and R2 consists of straightforward rectangle of polysilicon lines 100 and 120, with a regular repeating pattern of off-edge contact extensions. Resistors R1 and R2 consisted of polysilicon lines 100 and 120 have advantages in that they can avoid pinching effects of diffusion resistor that reveals nonlinear feature with applied voltage. Further, polysilicon resistors R1 and R2 can be used to obtain higher resistance where wide tolerances are permissible. Typically, an undoped polysilicon film is deposited for this purpose, and subsequently implanted with an impurity. This is followed by an anneal step which increases the grain size and lowers the resistivity of the polysilicon film. The polysilicon lines 100 and 120 may be silicided layers.

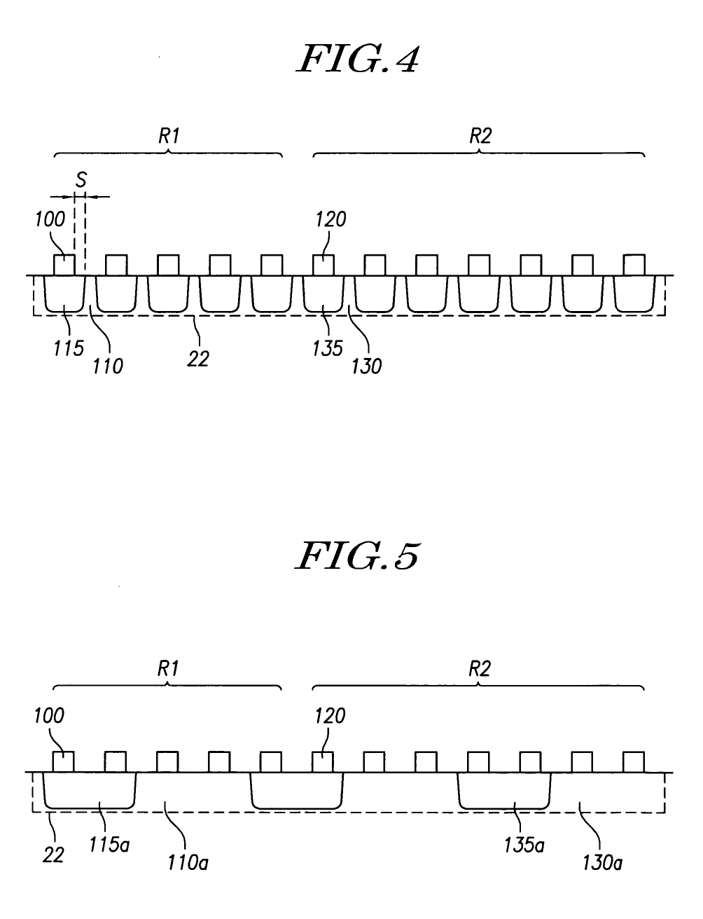

Referring to FIG. 3 and FIG. 4 that shows the cross-section of resistors R1 and R2 when taken along the line IV-IV of FIG. 3, the polysilicon lines 100 and 120 are formed on narrow STIs 115 and 135 each of which are separated by active dummy layers 110 and 130, respectively. The narrow STIs 115 and 135 have greatly reduced width when compared to the conventional STI 22 (as denoted by dotted line in FIG. 4). This results in the prevention of the STI dishing problem observed in the conventional resistors.

It is preferable for the space “S” between each of resistor layers 100 and 120 and each edge of narrow STIs 115 and 135 to be kept equal to or greater than the depth “D” of the narrow STIs 115 and 135 in order to avoid coupling noise due to the sandwiched active dummy layers 110 and 130.

FIG. 5 is a cross-sectional view of resistors according to another embodiment of the present invention.

Referring to FIG. 5, every two resistor layers are formed on each of narrow STIs 115a and 135a, unlike the resistor structure of FIG. 3 where each of the resistor layers is formed on corresponding single narrow STI 115. Therefore, ordinary skilled in the art would easily understand that the number of narrow STIs and active dummy layers are not limited to the structures of FIGS. 4 and 5 and it can be modified within the spirit and scope of the present invention.

The process for forming the resistors on the narrow STI is explained below.

Active regions where circuit elements such as transistors are to be formed and field regions that electrically separate the active regions are defined. The formation of the active and field regions starts with deposition of a pad oxide on a semiconductor substrate. Then, a silicon nitride is deposited on the pad oxide using e.g., chemical vapor deposition (CVD) method.

Photoresist is deposited on the entire surface of the substrate, and patterns of trench including narrow trenches as shown in FIG. 4 or 5 are transferred to the photoresist from a photo-mask. The silicon nitride and pad oxide are selectively removed by e.g., plasma etching with the photoresist pattern as a mask. The selectively etched silicon nitride and pad oxide expose the surface of the semiconductor substrate at the portions where a plurality of trenches are formed. Then, a silicon substrate is etched and a plurality of trenches are formed in the semiconductor substrate.

In the present invention, the photo-mask having patterns of trenches define narrow trenches the active dummy patterns which are sandwiched by neighboring narrow trenches.

Then, oxide film is deposited on the entire surface of the semiconductor substrate to fill the trenches. The oxide fill may be formed by plasma-enhanced CVD (PECVD) method. The oxide fill is polished by e.g., chemical mechanical planarization (CMP) method, until top surface of polished oxide fill equals to the top surface of the remaining silicon nitride. Subsequently, the silicon nitride and pad oxide are completely removed.

Thereafter, polycrystalline silicon is deposited on the semiconductor substrate at the field regions and photoresist is deposited on the polysilicon. Patterns of polysilicon lines are transferred to the photoresist and the polysilicon is selectively etched away by a photolithographic process to form resistor lines as shown in FIG. 3. At this stage, the selective removal of polysilicon leaves lines of polysilicon on the narrow trenches. Subsequently, metal contacts to off-edge of the polysilicon lines are formed.

In the present invention, active dummy layers are formed commonly with the same photo-mask for the trenches. That is, the present invention can be accomplished without any additional photo-masks and photolithographic processing steps for the active dummy layers. By modifying patterns on the photo-mask for the conventional wide trenches, the active dummy layers are obtained.

Further, with the present invention, critical dimension of passive components can be kept constant and the ratio of several resistors is uniformly controlled so that microcircuits employing passive components can meet designed specifications such as output gain.

While the invention has been shown and described with reference to certain preferred embodiments thereof, it will be understood by those skilled in the art that various changes in form and details may be made therein without departing from the spirit and scope of the invention as defined by the appended claims. For instance, the present invention can be applied to other passive components such as inductors and capacitors.

What is claimed is:

1. A method for forming resistors in semiconductor integrated circuit device, comprising the steps of:
depositing a pad oxide on a semiconductor substrate;
depositing silicon nitride on the pad oxide;
depositing photoresist on entire surface of the substrate;
transferring patterns of trenches to the photoresist to form photoresist pattern, said patterns of trenches including narrow trenches and active dummy layers sandwiched between neighboring narrow trenches;
selectively removing the silicon nitride and pad oxide with using the photoresist pattern as a mask;
selectively etching the semiconductor substrate at portions that are exposed by the selectively removed silicon nitride and pad oxide to form trenches including the narrow trenches;
forming polysilicon lines on the narrow trenches; and
forming metal contacts to off-edges of the polysilicon lines.

2. The method of claim 1, wherein a space between each of the polysilicon lines and an edge of the narrow trench on which the polysilicon line is formed is equal to or greater than a depth of the narrow trench.

3. The method of claim 1, wherein the step for forming the polysilicon lines includes silicidation of the polysilicon lines.

4. The method of claim 1, wherein the step for forming the polysilicon lines comprises the steps of:
depositing undoped polysilicon on the semiconductor substrate;
implanting impurity ions into the deposited undoped polysilicon; and
annealing the polysilicon to increase grain size and resistivity of the polysilicon.

5. The method of claim 1, wherein each of the polysilicon lines is formed on every narrow trench.

6. The method of claim 1, wherein each of the polysilicon lines is formed on every two narrow trenches.
